(19) United States
(12) Patent Application Publication
(10) Pub. No.: US 2020/0273955 A1
(43) Pub. Date: Aug. 27, 2020

(54) ROOM-TEMPERATURE FERROMAGNETIC SEMICONDUCTOR LAYERS, ELECTRONIC DEVICES INCLUDING THE SAME, AND METHODS OF FORMING THE SAME

(71) Applicant: North Carolina State University, Raleigh, NC (US)

(72) Inventors: Linyou Cao, Cary, NC (US); Guoqing Li, Raleigh, NC (US)

(21) Appl. No.: 16/798,501

(22) Filed: Feb. 24, 2020

Related U.S. Application Data
(60) Provisional application No. 62/811,085, filed on Feb. 27, 2019.

(51) Int. Cl. H01L 29/24; H01L 29/43; H01L 21/02; H01L 43/10

(52) U.S. Cl. CPC H01L 29/24; H01L 29/43; H01L 43/10; H01L 21/0257; H01L 21/0262; H01L 21/02568

(57) ABSTRACT

Ferromagnetic semiconductor layers and methods of forming the same are provided. Electronic devices including the ferromagnetic semiconductor layer are also provided. The ferromagnetic semiconductor layer may include an atomically thin transition metal dichalcogenide layer. The atomically thin transition metal dichalcogenide layer may include dopant metal atoms therein.

### CROSS-REFERENCE TO RELATED APPLICATION

This application claims priority to U.S. Provisional Application Ser. No. 62/811,085, entitled ROOM-TEMPERATURE FERROMAGNETIC SEMICONDUCTOR LAYERS ELECTRONIC DEVICES INCLUDING THE SAME, AND METHODS OF FORMING THE SAME, filed in the USPTO on Feb. 27, 2019, the disclosure of which is hereby, incorporated by reference herein in its entirety.

### STATEMENT OF GOVERNMENT SUPPORT

This invention was made with government support under grant number 1741693 awarded by the National Science Foundation. The government has certain rights in the invention.

### TECHNICAL FIELD

The present disclosure relates to ferromagnetic semiconductor layers, electronic devices including the same, and methods of forming the same.

### BACKGROUND

Semiconductor layers with strong magnetic properties may be beneficial to electronic devices such as magnetic bipolar transistors and magnetic storage devices. Ferromagnetic semiconductor layers may allow control of quantum spin state which may be critical for spintronic applications. Dilute magnetic semiconductors (DMS) have been researched to introduce ferromagnetism to semiconductor materials. However, DMS may have short-range ferromagnetic order, and the Curie temperature may not be high enough.

### SUMMARY

According to some embodiments of the present inventive concepts, ferromagnetic semiconductor layers may include an atomically thin transition metal dichalcogenide layer. The atomically thin transition metal dichalcogenide layer may include dopant metal atoms.

According to some embodiments of the present inventive concepts, methods of forming the ferromagnetic semiconductor layer may include reacting a first precursor gas including transition metal atoms with a second precursor gas including chalcogenide atoms and a third precursor gas including the dopant metal atoms to form a gaseous compound including the transition metal atoms, the chalcogenide atoms, and the dopant metal atoms and precipitating the atomically thin transition metal dichalcogenide layer on a substrate (e.g., a wafer having a diameter in a range of about 25 mm to 300 mm.

According to some embodiments of the present inventive concepts, electronic devices may include the ferromagnetic semiconductor layer therein.

### BRIEF DESCRIPTION OF THE DRAWINGS

FIG. 1A is a Scanning Transmission Electron Microscopy (STEM) image of a monolayer Pt-MoS₂ film with a Pt concentration of about 6.4 atom percentage. The hole in the center is caused by TEM grids during the measurement. Pt atoms form lines along the grain boundaries of the polycrystalline MoS₂ film.

FIG. 1B is a modeled crystal structure of Pt-MoS₂ monolayer film.

FIG. 1C shows Raman spectra of a pure MoS₂ film and a Pt-MoS₂ (with 6.4 atom percentage of Pt) film. Compared with the pure MoS₂ film, the Pt-MoS₂ film shows two extra peaks at 220 cm⁻¹ and 305 cm⁻¹ because of Pt atoms.

FIG. 1D shows PL spectra of a pure MoS₂ film and a Pt-MoS₂ (with 6.4 atom percentage of Pt) film. The pure MoS₂ film shows higher PL intensity.

FIG. 1E shows XPS spectra of a pure MoS₂ film and a Pt-MoS₂ (with 6.4 atom percentage of Pt) film.

FIGS. 2A and 2B are graphs showing ferromagnetic characteristics of a monolayer Pt-MoS₂ film. FIG. 2A is in-plane M-H curves of a pure MoS₂ film, a Pt-MoS₂ film and a SiO₂/Si substrate at a temperature of 5K. Diamagnetism signal was observed from the SiO₂/Si substrate and the pure MoS₂ film. While the Pt-MoS₂ film shows ferromagnetism behavior. FIG. 2B shows temperature dependence of ferromagnetic moments of the Pt-MoS₂ sample. The saturated magnetic moment and coercivity decrease as temperature increases.

FIGS. 3A, 3B and 3C are graphs showing in-plane and out-of-plane magnetism dependence on a Pt concentration and a number of layers in MoS₂ thin film at room temperature. FIG. 3A is a graph showing dependence of in-plane magnetic moment on a Pt concentration in the MoS₂ monolayer film. FIG. 3B is a graph showing dependence of out-of-plane magnetic moment on a Pt concentration in the MoS₂ monolayer film. FIG. 3C is a graph showing of in-plane magnetic moment on a number of MoS₂ layers.

FIGS. 4A and 4B are graphs showing PL spectra and H-M lops, respectively, of high quality and low quality monolayer MoS2 films with similar amount of Pt concentration.

FIG. 5A is an optical image of monolayer Pt-MoS₂ film on SiO2/Si substrate. A scratch was made intentionally to see the contrast. FIG. 5B shows an AFM image of monolayer Pt-MoS₂ film (left) and an AFM of a film with phase separation when the Pt precursor amount is high (right).

### DETAILED DESCRIPTION

Two dimensional materials (e.g., an atomically thin layer) may have unique optical, electrical, and mechanical properties compared with traditional three-dimensional materials. Therefore, processes of forming room-temperature ferromagnetic two dimensional materials have been researched. Recently, engineering has been performed to achieve room temperature ferromagnetic behavior of graphene. However, graphene may lack semiconducting properties due to its metallic conductivity. Semiconductors having ferromagnetism may be applicable to various electronic devices, for example, electric motors, transformers, magnetic storage, and spintronic devices. Therefore, two dimensional materials having strong room temperature magnetic properties and strong semiconductor properties (e.g., high carrier mobility) may be beneficial to various electronic devices.

Molybdenum disulfide (MoS₂) has been considered as among materials suitable for spintronic applications due to its well-defined spin-splitting property. However, 2H phase pure (e.g., not intentionally doped) MoS₂ may have no ferromagnetic property. To obtain ferromagnetic MoS₂ thin film, various methods have been developed. For instance, defect engineering has been applied to create ferromagnetic moment. However, introduction of defects could lead to poor semiconducting functionalities of the MoS₂ thin films. Doping MoS₂ with magnetic metal atoms, such as Ni, Fe and Co, has been applied to create ferromagnetic moment in MoS₂ thin films. However, sources of ferromagnetic moment of the MoS₂ thin films may be unclear, and the MoS₂ thin films do not show the long-range ferromagnetic order.

According to some embodiments of the present inventive concepts, an atomically thin MoS₂ layer doped with platinum (Pt) atoms is provided. The MoS₂ layer may have room-temperature ferromagnetic moment. Density Functional Theoretical (DFT) calculations suggest that one of sources of ferromagnetism may be the aligned Pt chains in grain boundaries of MoS₂ polycrystalline films. The ferromagnetic moment may be controlled by changing concentrations of Pt atoms and lengths of the Pt chains, and the concentrations of Pt atoms and the lengths of the Pt chains may be controlled by changing an amount of Pt precursor during a process of forming the MoS₂ layer. A thickness of the MoS₂ layer may be controlled by changing Mo precursor amount. The ferromagnetic behavior may show dependence on a length of a Pt chain and a concentration of Pt atoms but may not show dependence on a number of MoS₂ layers in a film.

In some embodiments, a MoS₂ layer according to some embodiments of the present inventive concepts may include an edge free MoS₂ film and Pt atoms, which are both paramagnetic, and may show room-temperature ferromagnetism. Density Function Theoretical (DFT) calculation suggests Pt atom chains in mirror grain boundaries may be among main sources of ferromagnetism. The presence of Pt atom chains was confirmed by high resolution Scanning Transmission Electron Microscopy (STEM) characterization. The Pt-doped MoS₂ thin films show room-temperature ferromagnetism and semiconductor behavior (e.g., high carrier mobility). Additionally, the ferromagnetic behavior shows no layer dependence.

### Ferromagnetic Semiconductor Layers

According to some embodiments of the present inventive concepts, a ferromagnetic semiconductor layer may include an atomically thin transition metal dichalcogenide layer that includes dopant metal atoms. The ferromagnetic semiconductor layers may be ferromagnetic semiconductor at room temperature (e.g., 300K). In some embodiments, the atomically thin transition metal dichalcogenide layer is a polycrystalline layer including multiple grains therein, and the dopant metal atoms may be in grain boundaries of the atomically thin transition metal dichalcogenide layer.

In some embodiments, the dopant metal atoms may be in the grain boundaries of the atomically thin transition metal dichalcogenide layer and may not be in the grains of the atomically thin transition metal dichalcogenide layer. The dopant metal atoms may form a linear chain, and ferromagnetic momentum may vary according to a number of the dopant metal atoms included in the linear chain. For example, the linear chain of the dopant metal atoms comprises more than 5 dopant metal atoms (e.g., 6 dopant metal atoms, 7 dopant metal atoms, 8 dopant metal atoms, 9 dopant metal atoms, 10 dopant metal atoms, 11 dopant metal atoms, 12 dopant metal atoms, 13 dopant metal atoms, 14 dopant metal atoms, 15 dopant metal atoms, 16 dopant metal atoms, 17 dopant metal atoms, 18 dopant metal atoms, 19 dopant metal atoms, or 20 dopant metal atoms).

For example, the dopant metal atoms may include iron (Fe) atoms, nickel (Ni) atoms, cobalt (Co) atoms, platinum (Pt) atoms, magnesium (Mg) atoms, rhenium (Re) atoms, and/or Niobium (Nb) atoms. The atomically thin transition metal dichalcogenide layer may include, for example, MoS₂, WS₂, WSe₂, MoSe₂, MoTe₂, WTe₂, and/or an alloy thereof.

In some embodiments, the atomically thin transition metal dichalcogenide layer may be a monolayer film or a film including less than 10 layers (e.g., 1 layer, 2 layers, 3 layers, 4 layers, 5 layers, 6 layers, 7 layers, 8 layers, 9 layers). The atomically thin transition metal dichalcogenide layer may have a thickness of about 10 nm or less (e.g., 1 nm, 2 nm, 3 nm, 4 nm, 5 nm, 6 nm, 7 nm, 8 nm, 9 nm, or 10 nm).

In some embodiments, the ferromagnetic semiconductor layer may have a magnetic momentum equal to or greater than 500 emu/cm (e.g., 500 emu/cm, 510 emu/cm, 520 emu/cm, 530 emu/cm, 540 emu/cm, 550 emu/cm, 600 emu/cm, 650 emu/cm) and coercivity equal to greater than 70 Oe (e.g., 70 Oe, 80 Oe, 90 Oe, 100 Oe, 110 Oe, 120 Oe) at a temperature of 300K.

In some embodiments, an atomic percentage of the dopant metal atoms in the ferromagnetic semiconductor layer is equal to or greater than 3 at. % (e.g., 3 at. %, 3.5 at. %, 4 at. %, 4.5 at. %, 5 at. %, 5.5 at. %, 6 at. %, 6.5 at. %, 7 at. %, 7.5 at. %, 8 at. %, 8.5 at. %, 9 at. %, 9.5 at. %, or 10 at. %).

### Method of Forming Ferromagnetic Semiconductor Layer

The atomically thin transition metal dichalcogenide layer of the ferromagnetic semiconductor layer may be formed using methods similar to the method discussed in U.S. Pat. No. 9,527,062. Processes according to some embodiments of the present inventive concepts may be the same as or similar to the process discussed in U.S. Pat. No. 9,527,062, in some aspects, but may further include using a precursor including dopant metal atoms for in-situ doping of dopant metal atoms to the atomically thin transition metal dichalcogenide layer.

The method may include sublimating a first precursor powder including transition metal atoms, a second precursor powder including chalcogenide atoms, and a third precursor powder including dopant metal atoms to provide a first precursor gas including the transition metal atoms, a second precursor gas including the chalcogenide atoms, and a third precursor gas including the dopant metal atoms, respectively.

The method may also include reacting the first precursor gas with the second precursor gas and the third precursor gas to form a gaseous compound including the transition metal atoms, the chalcogenide atoms, and the dopant metal atoms. The gaseous compound may be transferred toward a substrate (e.g., a wafer having a diameter in a range of about 25 mm to 300 mm) using a carrier gas and then may be diffused onto the substrate. The diffused gaseous compound may be precipitated on the substrate.

In some embodiments, the carrier gas may be a mixture of argon and hydrogen, and a volume ratio of argon to hydrogen is in a range of 80:20 to 99:1 (e.g., 80:20, 85:15, 90:10, 95:5, and 99:1). For example, the first precursor powder may include MoCl₅, MoCl₃, MoO₂Cl₂, MoOCl₃, WCl₆, MoO₃, WO₃, Mo(CO)₆, W(CO)₆, a compound comprising Mo and/or a compound comprising W. For example, the second precursor powder may include sulfur powder, and a third precursor powder may include Platinum (II) acetyl acetonate (Pt(acac)₂).

In some embodiments, the method may be performed at a temperature in a range of about 300° C. to about 1000° C. (e.g., 300° C., 350° C., 400° C., 450° C., 500° C., 550° C., 600° C., 650° C., 700° C., 750° C., 800° C., 850° C., 900° C., 950° C., and 1000° C.) and at a pressure in a range of about 1 Torr to 4 Torr (e.g., 1 Torr, 1.5 Torr, 2 Torr, 2.5 Torr, 3 Torr, 3.5 Torr, and 4 Torr).

In some embodiments, the first precursor gas, the second precursor gas, and the third precursor gas may be supplied at a flow rate of in a range of about 20 sccm to about 80 sccm (e.g., 20 sccm, 25 sccm, 30 sccm, 35 sccm, 40 sccm, 45 sccm, 50 sccm, 55 sccm, 60 sccm, 65 sccm, 70 sccm, 75 sccm, and 80 sccm).

In some embodiments, the substrate may include a silicon substrate and a silicon oxide layer, and the atomically thin transition metal dichalcogenide layer may be formed on the silicon oxide layer such that the silicon oxide layer may extend between the silicon substrate and the atomically thin transition metal dichalcogenide layer.

### Applications

The ferromagnetic semiconductor layer according to some embodiments of the present inventive concepts may be included in various electronic devices. For example, the ferromagnetic semiconductor layer may be included in a single-photon emitter, a magnetic field sensor, a magneto-optical device, a transistor, or a memory device.

In some embodiments, the ferromagnetic semiconductor layer may be included in a gate electrode of a transistor. In some embodiments, the ferromagnetic semiconductor layer may be included in a data storage element of a memory device (e.g., a magnetoresistive random-access memory)

### Examples

The following examples describe some embodiments of the present inventive concepts. While embodiments of the present inventive concepts are described in connection with the following examples and the corresponding text and figures, there is no intent to limit embodiments of the present inventive concepts to this description.

### Synthesis and Transfer of Monolayer MoS₂Films and Flakes

Pt doped MoS₂ films were synthesized using a chemical vapor deposition process similar in at least some aspects to that discussed in U.S. Pat. No. 9,527,062. Molybdenum chloride (MoCl₃) powder (99.99%, Sigma-Aldrich), sulfur powder (99%, Sigma-Aldrich), and Platinum (II) acetylacetonate (Pt(acac)₂) (97%, Sigma-Aldrich) were used as Molybdenum, sulfur and platinum precursors respectively. Argon (Ar)/H₂ (Vol ratio 95:5) mixture gas was used as the carrier gas. Receiving substrates are 300 nm SiO₂/Si wafers (university wafers Inc). Typical synthesis conditions include a temperature of 850° C., a flow rate of 50 sccm, and a pressure around 2 Torr. The films with different Pt dopant concentrations were prepared by controlling the P (acac)₂ precursor amounts.

### Structure and Composition Characterizations

Raman and photoluminescent (PL) measurements were carried out using a Horiba xPlora system equipped with an excitation wavelength at 532 nm. Atomic Force Microscopy (AFM) measurements were performed at an asylum MFP-3000 atomic force microscope. X-ray Photoelectron Spectroscopy (XPS) measurements were carried out at X-ray photoelectron spectroscope (SPECS System with PHOIBOS 150 analyzer using an Mg Kα X-ray source). Annular dark-field (ADF) STEM images and HRTEM images were acquired using an aberration-corrected JEOL JEM-ARM200CF scanning transmission electron microscope operated at 80 kV. ADF images were processed with a deconvolution filter to improve the contrast. Magnetization measurements were performed at 5K-300K in a Quantum Design SQUID VSM. The magnetic field was applied parallelly or vertically to the samples that were mounted on a diamagnetic quartz sample holder to measure the in-plane and out-plane magnetic moments respectively.

### Device Fabrication and Measurement

The field-effect transistor device was fabricated by evaporating Ti/Au (5/200 nm) electrodes directly onto top of Pt-MoS₂ films on SiO₂/Si substrates with 300 nm thick silicon oxide. A copper grid (100 mesh, 30 microns spacing, Ted Pella) was placed on top of the thin film as mask for the electrode fabrication. This gives a relatively large channel with a length L=30 μm and a width W=230 μm. The electrical measurements were performed in ambient conditions using a probe station (Karl Suss PSM6).

### Results and Discussion

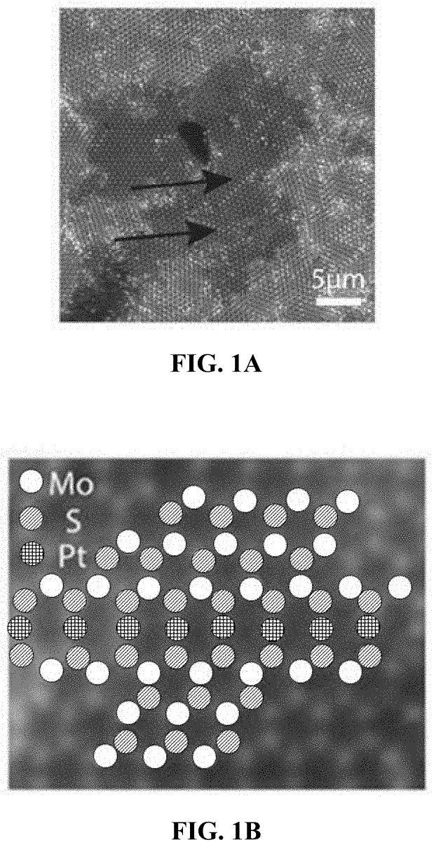

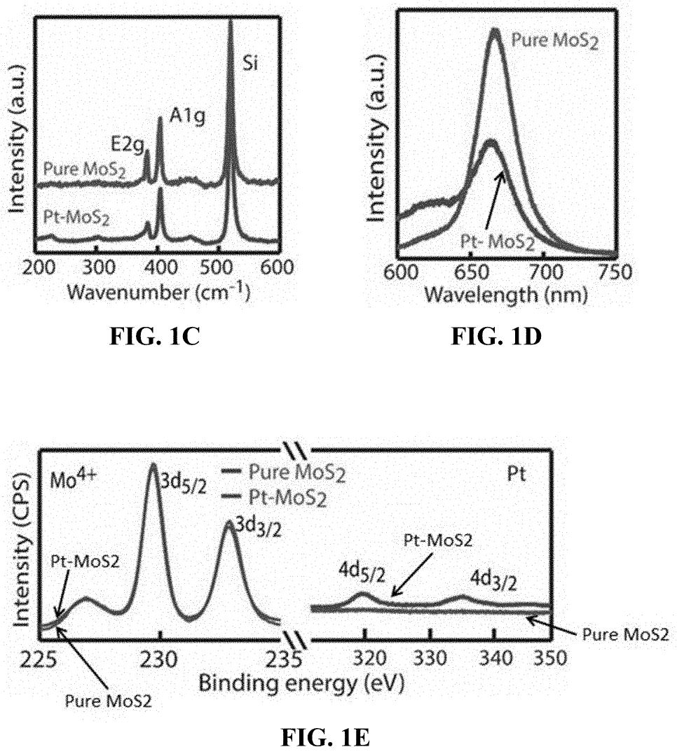

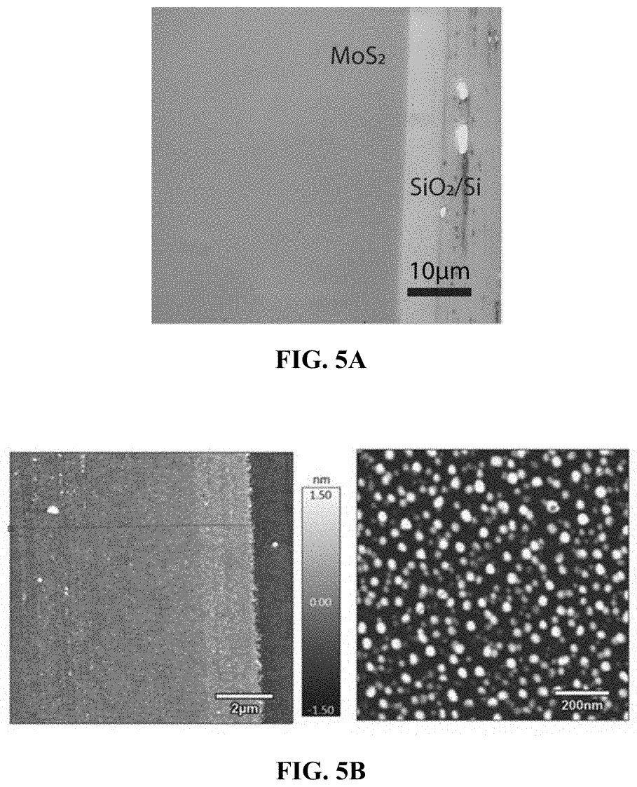

Pure MoS₂ monolayer films and Pt-doped MoS₂ monolayer films on SiO₂/Si substrates were synthesized using some aspects of a self-limiting chemical vapor deposition method discussed in U.S. Pat. No. 9,527,062. The edges of MoS₂ have been reported to possess ferromagnetism. Therefore, edge-free continuous thin films were synthesized. It was confirmed that the doped and undoped films are very uniform in both composition and structure, and the films cover the SiO₂/Si supporting substrates with no observable crakes or cracks as shown in FIG. 5A. A STEM image in FIG. 1A shows that platinum atoms chains are formed along the boundaries of MoS₂. Pt chain lengths and concentrations of Pt in MoS₂ film were controlled by controlling Pt precursor amount. The accurate concentration of Pt was confirmed with XPS measurements. Raman and PL measured were done to characterize the pure and Pt-doped MoS₂ films. When the Pt dopant concentration is low (less than 3 atom percentage), the change of Raman is not clear. While the PL starts to decrease. With increasing Pt dopant concentration, two peaks at around 220 cm⁻¹ and 305 cm⁻¹ appeared and became stronger. Meanwhile, the Alg peak of MoS₇ became broader and weaker. The PL continuously decreased until it disappears. To obtain appropriate semiconductor properties, the Pt dopant concentration needs to be kept under a certain level. Also, at certain high Pt dopant concentration, aggregation of Pt particles was observed on the surface of MoS₂ films as shown in FIG. 5B.

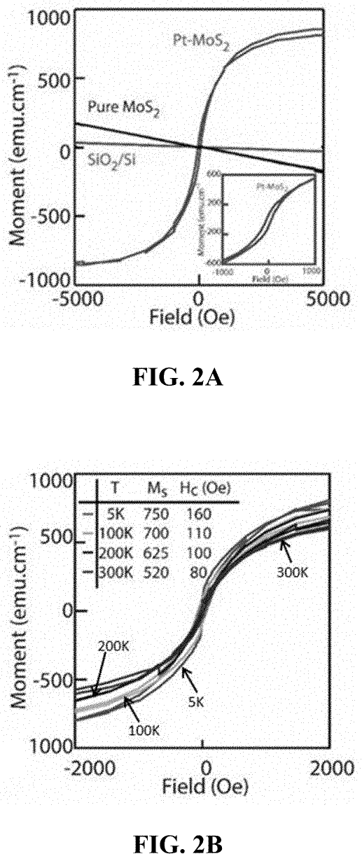

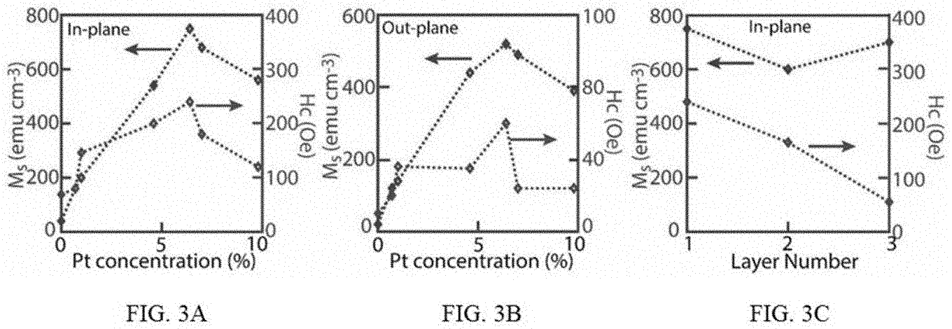

For comparison, magnetic behavior of a pure MoS₂ monolayer, a Pt-doped MoS₂ monolayer, and a bare SiO₂/Si substrate were measured using SQUID. Both the edge free MoS₂ monolayer and a bare SiO₂/Si substrate show paramagnetic behavior at all measured temperatures. While, Pt-MoS₂ films show ferromagnetic moment not only at low temperature (5K) but also at room temperature (300K) at certain Pt dopant concentrations as shown in FIG. 2B. At 5K, the Pt-MoS₂ monolayer film shows its ferromagnetic behavior. A saturated magnetic moment and coercivity can reach 750 emu·cm⁻¹ and 160 Oe, respectively. The pure and Pt-MoS₂ films were synthesized using the same setup following a similar synthesis process. Therefore, it is reasonable to conclude that the ferromagnetic behavior observed in the Pt-MoS₂ film is not from the possible contaminations during the synthesis, handling and measurement processes. A major difference between the pure MoS₂ monolayer and the Pt-MoS₂ monolayer is that the Pt-MoS₂ films have large amount of well-distributed Pt atom chains on the grain boundaries, which could be the source of magnetism of Pt-MoS₂ films.

To further confirm that the Pt atom chains in the grain boundaries are a source of the magnetism on Pt-MoS₂ films, an edge-free monolayer Pt-MoS₂ film was prepared. The edge-free monolayer Pt-MoS₂ films include various amounts of grain boundaries with different length per unit area due to different grain sizes which is determined by the quality of the film. Meanwhile, Pt chains with different length and concentrations could be obtained. In general, the higher the quality, the longer but less boundaries per unit area will be in the films. The quality is closely affected by the ratio of the precursor Pt(acac)₂ to MoCl₃. Therefore, to control the length and concentration of Pt chains, different platinum precursor amounts were used during the CVD synthesis while keeping the Mo precursor amount constant. The accurate platinum amount in Pt-MoS₂ films were obtained by XPS measurement (FIG. 1E). The ferromagnetic moments of Pt-MoS₂ films with different Pt dopant concentrations show differences (FIG. 2A). When the Pt dopant concentration is below 6.4%, the ferromagnetic moment is increasing with Pt dopant concentrations. It reaches the strongest magnetism with a saturation magnetic moment of 750 emu/cm³ and a coercivity of 240 Oe when the Pt concentration is 6.4 at. % and then begins to decrease as Pt dopant concentration increases. The out-of-plane magnetic behavior of monolayer with different amount and length of Pt chains was also characterized. The dependence of magnetic moment and coercivity on Pt concentration shows a similar trend with the in-plane magnetism. To study effect of a number of layers on magnetism behavior, Pt-MoS₂ films with different numbers of layers but similar Pt concentrations were synthesized. The numbers of layers were identified and confirmed by Raman spectra and AFM measurements (See FIG. 5B). There is no clear difference in the saturated magnetic moment of samples with different numbers of layers. However, the coercivity shows certain degree of decrease as the number of layers increases. The magnetic measurements of monolayer to three-layers MoS₂ films show that the ferromagnetic moment shows no layer dependence. According to the STEM images, there is no difference between the Pt chains formed in different layers. The ferromagnetic moments of the whole films may be caused by the addition of the ferromagnetic moments of each layer. Therefore, the ferromagnetic moment per unit volume may be maintained regardless of how many layers the films have. It was confirmed that all the films studied have no phase separation by AFM measurements (See FIG. 5B).

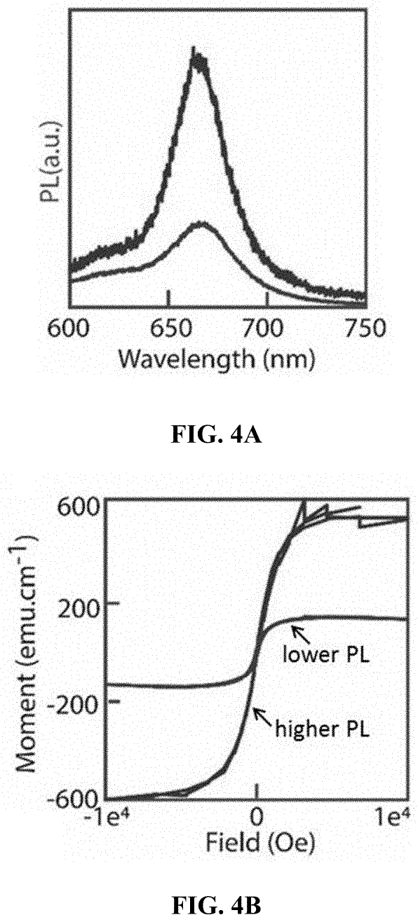

The quality of MoS₂ film also showed significant influence on the magnetic orders of the doped films. Two films with the same Pt concentration but different qualities were prepared. The ferromagnetic moments show difference for these two samples. The one with better quality (higher PL) shows much stronger ferromagnetic moment that the one with lower quality (lower PL) as shown in FIG. 4B. To identify possible reasons, STEM images are taken. The Pt-MoS₇ films showing higher PL has much longer Pt chains (e.g., 10-12 atoms per chain) on the boundaries than the one with lower PL (e.g. 3-6 atoms per chain). Therefore, the ferromagnetic moment of Pt-MoS₂ films is dependent on length and concentration of Pt chains in the boundaries, which can be affected by the quality of the MoS₂ films.

To test the semiconductor behavior of Pt-MoS₂ films, a field-effect transistor device was fabricated. Reasonable gating behavior and mobility was obtained from the Pt-MoS₂ film with room temperature ferromagnetism. This matches the observation of reasonable strong PL signals on those Pt-MoS₂ films.

MoS₂ films with their grain boundaries decorated by Pt chains with different concentrations and length were fabricated and showed both strong semiconductor properties and room-temperature ferromagnetism. The ferromagnetic moment may depend on a length of the Pt chains and may not have dependence on a number of layers. The fabricated Pt-MoS₂ films showed in-plane and out-plane ferromagnetism.

It will be understood that the present inventive concepts are not limited to particular embodiments described herein, and as such may, of course, vary. It is also to be understood that the terminology used herein is for the purpose of describing particular embodiments only, and is not intended to be limiting.

All publications and patents cited in this specification are herein incorporated by reference in a matter consistent with the present application as if each individual publication or patent were specifically and individually indicated to be incorporated by reference and are incorporated herein by reference to disclose and describe the methods and/or materials in connection with which the publications are cited.

Functions or constructions well-known in the art may not be described in detail for brevity and/or clarity. Embodiments of the present inventive concepts will employ, unless otherwise indicated, techniques of nanotechnology, organic chemistry, material science and engineering and the like, which are within the skill of the art.

It should be noted that ratios, concentrations, amounts, and other numerical data can be expressed herein in a range format. It will be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to about 5%” should be interpreted to include not only the explicitly recited values of about 0.1% to about 5%, but also include individual values (e.g., 1%, 2%, 3%, and 4%) and the sub-ranges (e.g., 0.5%, 1.1%, 2.2%, 3.3%, and 4.4%) within the indicated range. Where the stated range includes one or both of the limits, ranges excluding either or both of those included limits are also included in the disclosure, e.g., the phrase “x to y” includes the range from ‘x’ to ‘y’ as well as the range greater than ‘x’ and less than ‘y’. The range can also be expressed as an upper limit, e.g., ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In some embodiments, the term “about” can include traditional rounding according to significant figures of the numerical value. In addition, the phrase “about ‘x’ to ‘y’”, where ‘x’ and ‘y’ are numerical values, includes “about ‘x’ to about ‘y’”.

Unless defined otherwise, all technical and scientific terms used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

The articles “a” and “an,” as used herein, mean one or more when applied to any feature in embodiments of the present inventive concepts described in the specification and claims. The use of “a” and “an” does not limit the meaning to a single feature unless such a limit is specifically stated. The article “the” preceding singular or plural nouns or noun phrases denotes a particular specified feature or particular specified features and may have a singular or plural connotation depending upon the context in which it is used. As used herein the term “and/or” includes any and all combinations of one or more of the associated listed items. Like reference numbers refer to like elements throughout.

The following claims are provided to ensure that the present application meets all statutory requirements as a priority application in all jurisdictions and shall not be construed as setting forth the scope of the present invention.

Which is claimed is:

1. A ferromagnetic semiconductor layer comprising an atomically thin transition metal dichalcogenide layer, wherein the atomically thin transition metal dichalcogenide layer comprises dopant metal atoms.

2. The ferromagnetic semiconductor layer of claim 1, wherein the atomically thin transition metal dichalcogenide layer is a polycrystalline layer comprising a plurality of grains, and
wherein the dopant metal atoms are in a grain boundary of the atomically thin transition metal dichalcogenide layer.

3. The ferromagnetic semiconductor layer of claim 2, wherein the dopant metal atoms form a linear chain.

4. The ferromagnetic semiconductor layer of claim 3, wherein the linear chain of the dopant metal atoms comprises more than 5 dopant metal atoms.

5. The ferromagnetic semiconductor layer of claim 1, wherein the dopant metal atoms comprises iron (Fe) atoms, nickel (Ni) atoms, cobalt (Co) atoms, platinum (Pt) atoms, magnesium (Mg) atoms, rhenium (Re) atoms, and/or Niobium (Nb) atoms.

6. The ferromagnetic semiconductor layer of claim 1, wherein the atomically thin transition metal dichalcogenide layer comprises MoS₂, WS₂, WSe₂, MoSe₂, MoTe₂, WTe₂, and/or alloys thereof.

7. The ferromagnetic semiconductor layer of claim 1, wherein the atomically thin transition metal dichalcogenide layer has a thickness of about 10 nm or less.

8. The ferromagnetic semiconductor layer of claim 1, wherein the atomically thin transition metal dichalcogenide layer is a monolayer film or a film comprising less than 10 layers.

9. The ferromagnetic semiconductor layer of claim 1, wherein the ferromagnetic semiconductor layer has a magnetic momentum equal to or greater than 500 emu/cm and coercivity equal to or greater than 70 Oe at a temperature of 300K.

10. The ferromagnetic semiconductor layer of claim 1, wherein an atomic percentage of the dopant metal atoms in the ferromagnetic semiconductor layer is equal to or greater than 3 at. %.

11. An electronic device comprising the ferromagnetic semiconductor layer of claim 1.

12. The electronic device of claim 11, wherein the electronic device comprises a transistor that comprises the ferromagnetic semiconductor layer in a gate electrode of the transistor.

13. The electronic device of claim 11, wherein the electronic device comprises a memory device that comprises the ferromagnetic semiconductor layer in a data storage element.

14. The electronic device of claim 11, wherein the electronic device is a single-photon emitter, a magnetic field sensor, or a magneto-optical device.

15. A method of forming the ferromagnetic semiconductor layer of claim 1, the method comprising:
reacting a first precursor gas comprising transition metal atoms with a second precursor gas comprising chalcogenide atoms and a third precursor gas comprising the dopant metal atoms to form a gaseous compound comprising the transition metal atoms, the chalcogenide atoms, and the dopant metal atoms; and
precipitating the atomically thin transition metal dichalcogenide layer on a substrate.

16. The method of claim 15, further comprising:
transferring the gaseous compound toward the substrate using a carrier gas; and
diffusing the gaseous compound onto the substrate.

17. The method of claim 16, wherein the carrier gas comprises argon and hydrogen.

18. The method of claim 16, further comprising:
sublimating a first precursor powder comprising the transition metal atoms, a second precursor powder comprising the chalcogenide atoms, and a third precursor powder comprising the dopant metal atoms to provide the first precursor gas, the second precursor gas, and the third precursor gas, respectively.

19. The method of claim 18, wherein a volume ratio of argon to hydrogen is in a range of 80:20 to 99:1.

20. The method of claim 18, wherein the first precursor powder comprises MoCl₅, MoCl₃, MoO₂Cl₂, MoOCl₃, WCl₆, MoO₃, WO₃, Mo(CO)₆, W(CO)₆, a compound comprising Mo and/or a compound comprising W.
